(19) United States
(12) Patent Application Publication
(10) Pub. No.: US 2026/0186084 A1
(43) Pub. Date: Jul. 2, 2026

(54) METHOD FOR DETERMINING A MAGNETIZATION DIRECTION OF A WIEGAND WIRE, AND WIEGAND SENSOR ARRANGEMENT

(71) Applicant: FRABA B.V., SG HEERLEN (NL)

(72) Inventor: MATTHIAS LANSING, WUERSELEN (DE)

(73) Assignee: FRABA B.V., SG HEERLEN (NL)

(21) Appl. No.: 19/132,828

(22) PCT Filed: Dec. 13, 2022
(86) PCT No.: PCT/EP2022/085527

§ 371 Date: May 26, 2025

(51) Int. Cl. G01R 33/12; G01R 33/00

(52) U.S. Cl. CPC G01R 33/1215; G01R 33/0023

(57) ABSTRACT

A method for determining a direction of magnetization of a Wiegand wire. The method includes applying a test current which increases with time to a sensor coil which surrounds the Wiegand wire, detecting a sensor coil voltage which is present at the sensor coil during the applying of the test current, and comparing the sensor coil voltage which is detected during the applying of the test current with a reference voltage which increases simultaneously with the test current so as to determine the direction of magnetization. The reference voltage increases from a start reference voltage value to an end reference voltage value.

### CROSS REFERENCE TO PRIOR APPLICATIONS

This application is a U.S. National Phase application under 35 U.S.C. § 371 of International Application No. PCT/EP2022/085527, filed on Dec. 13, 2022. The International Application was published in German on Jun. 20, 2024 as WO 2024/125764 A1 under PCT Article 21(2).

### FIELD

The present invention relates to a method for determining a direction of magnetization of a Wiegand wire, wherein a test current which increases with time is applied to a sensor coil which surrounds the Wiegand wire, and a sensor coil voltage which is present at the sensor coil is detected during the applying of the test current. The present invention also relates to a Wiegand sensor arrangement comprising a Wiegand wire and a sensor coil surrounding the Wiegand wire.

### BACKGROUND

A Wiegand wire within the meaning of the present application is also referred to as an impulse wire and generally has a hard magnetic sheath and a soft magnetic core, or vice versa. Under the influence of an external magnetic field, the direction of magnetization of the Wiegand wire suddenly reverses, whereby a short Wiegand voltage pulse is generated in a sensor coil surrounding the Wiegand wire radially, which Wiegand voltage pulse can be detected via the two ends of the sensor coil. This effect is referred to as the Wiegand effect and is well known in the prior art.

Knowing the direction of magnetization of the Wiegand wire is important, for example, in a rotary encoder in order to carry out a synchronization between a Wiegand sensor-based revolution counter sensor unit, also known as a multiturn sensor unit, and a fine position sensor unit, also known as a singleturn sensor unit.

EP 1 565 755 B1 describes a method for determining a direction of magnetization of a Wiegand wire, wherein an increasing test current is applied to a sensor coil which surrounds the Wiegand wire and, during the applying of the test current, a sensor coil voltage, which is present at the sensor coil, is detected and evaluated.

### SUMMARY

An aspect of the present invention is to provide a relatively simple and reliable determination of the direction of magnetization of a Wiegand wire.

In an embodiment, the present invention provides a method for determining a direction of magnetization of a Wiegand wire. The method includes applying a test current which increases with time to a sensor coil which surrounds the Wiegand wire, detecting a sensor coil voltage which is present at the sensor coil during the applying of the test current, and comparing the sensor coil voltage which is detected during the applying of the test current with a reference voltage which increases simultaneously with the test current so as to determine the direction of magnetization. The reference voltage increases from a start reference voltage value to an end reference voltage value.

### BRIEF DESCRIPTION OF THE DRAWINGS

The present invention is described in greater detail below on the basis of embodiments and of the drawings in which:

FIG. 1 shows a schematic representation of a Wiegand sensor arrangement according to the present invention;

FIG. 2 shows a schematic representation of a magnetization direction determination unit of the Wiegand sensor arrangement of FIG. 1;

FIG. 3 shows exemplary temporal curves of a test current applied to a sensor coil of the Wiegand sensor arrangement of FIG. 1, a sensor coil voltage detected during the applying of the test current, and a reference voltage, for the case that a Wiegand voltage pulse is induced in the sensor coil;

FIG. 4 shows the temporal curves of the test current, the sensor coil voltage detected during the applying of the test current, and the reference voltage of FIG. 3, in the case where no Wiegand voltage pulse is induced in the sensor coil;

FIG. 5 shows a schematic representation of an alternative magnetization direction determination unit of the Wiegand sensor arrangement of FIG. 1;

FIG. 6 shows exemplary temporal curves of a calibration current applied to a sensor coil of the Wiegand sensor arrangement shown in FIG. 1 and a sensor coil voltage detected during the applying of the calibration current, as well as a calibration reference voltage value for the case that no Wiegand voltage pulse is induced in the sensor coil; and

FIG. 7 shows the temporal curves of the calibration current and the sensor coil voltage detected during the applying of the calibration current, as well as the calibration reference voltage value, for the case that a Wiegand voltage pulse is induced in the sensor coil.

### DETAILED DESCRIPTION

The method for determining a direction of magnetization of a Wiegand wire according to the present invention provides that a test current which increases over time is applied to a sensor coil surrounding the Wiegand wire in order to generate a test magnetic field acting on the Wiegand wire. The test current can, for example, increase continuously, i.e., steadily, from zero according to a defined test current curve. The test current can, for example, increase linearly with a defined gradient. The curve of the test current can be defined, for example, based on the results of laboratory tests. It is also conceivable to define different test current curves for different measurement conditions, for example, for different temperatures.

A so-called Wiegand voltage pulse is induced in the sensor coil by the Wiegand wire if the direction of magnetization is reversed by the generated test magnetic field. The occurrence or non-occurrence of a Wiegand voltage pulse can therefore be used to determine whether the direction of magnetization of the Wiegand wire was in the same direction or in the opposite direction to the test magnetic field before the test current was applied.

In the method for determining a direction of magnetization of a Wiegand wire according to the present invention, a sensor coil voltage which is present at the sensor coil is detected and evaluated during the applying of the test current.

In order to determine whether or not a Wiegand voltage pulse has been induced in the sensor coil and to determine the direction of magnetization of the Wiegand wire therefrom, the sensor coil voltage detected during the applying of the test current is compared with a reference voltage which increases simultaneously and, for example, uniformly with the test current, the reference voltage increasing from a defined start reference voltage value to a defined end reference voltage value. The start reference voltage value and the end reference voltage value can hereby be defined directly or indirectly, for example, via a predetermined mathematical relationship. The reference voltage can, for example, increase continuously, for example, linearly. It is conceivable, for example, that the end reference voltage value is defined indirectly via a predetermined gradient of the reference voltage. The comparison of the sensor coil voltage with the reference voltage can, for example, be performed via appropriate hardware, for example, via a comparator which compares the sensor coil voltage detected at the sensor coil with a reference voltage signal which increases simultaneously with the test current. The comparison of the sensor coil voltage with the reference voltage can in principle, however, also be implemented in software, wherein a sensor coil voltage variable which represents the detected sensor coil voltage is compared with a reference voltage variable which increases simultaneously with the test current.

The direction of magnetization is determined depending on whether the sensor coil voltage exceeds the reference voltage during the applying of the test current, i.e., whether or not it becomes greater than the reference voltage in terms of magnitude. If the sensor coil voltage exceeds the reference voltage, it is assumed that a Wiegand voltage pulse has been induced and that the Wiegand wire therefore had a direction of magnetization opposite to the test magnetic field before the test current was applied. The direction of magnetization is in this case set to a first magnetization direction value. If the sensor coil voltage does not exceed the reference voltage, it is assumed that no Wiegand voltage pulse has been induced and that the Wiegand wire therefore had a direction of magnetization in the same direction as the test magnetic field before the test current was applied. The direction of magnetization is in this case set to a second direction of magnetization value. In order to avoid an incorrect determination of the direction of magnetization due to voltage fluctuations, it may be advantageous to provide a specified minimum exceeding time as a criterion for exceeding the reference voltage, i.e., to set the direction of magnetization to the first direction of magnetization value only if the sensor coil voltage exceeds the reference voltage for the minimum exceeding time. The determined magnetization direction value is typically stored in a memory. It is also conceivable, however, that the magnetization direction value is not stored but only processed. A rotation count value can, for example, be determined or corrected based on the determined magnetization direction value.

The method according to the present invention therefore enables a simple and reliable determination of the direction of magnetization of a Wiegand wire.

The electrical properties of the sensor coil, in particular the electrical resistance of the sensor coil, are generally temperature-dependent, so that a voltage drop at the sensor coil caused by applying the test current to the sensor coil is also temperature-dependent according to Ohm's law. In the method according to the present invention, a temperature is therefore, for example, detected and the start reference voltage value and/or the end reference voltage value is defined on the basis of the detected temperature in order to enable a reliable determination of the direction of magnetization of the Wiegand wire independently of a present temperature.

In an embodiment of the method according to the present invention, a calibration can, for example, be performed before the applying of the test current. A calibration current, which can, for example, increase with time, is here applied to the sensor coil, which calibration current has a maximum calibration current value corresponding to 1/N times a maximum test current value of the test current, and the sensor coil voltage is detected during this time. The end reference voltage value up to which the reference voltage increases is then defined as the sum of the start reference voltage value and N times a maximum sensor coil voltage value detected during the applying of the calibration current. The end reference voltage value is therefore always greater than a maximum voltage drop caused by the test current at the sensor coil, so that exceeding the reference voltage due to the sensor coil voltage caused solely by the test current can be reliably prevented regardless of the current measurement conditions.

The sensor coil voltage detected during the applying of the calibration current can, for example, be compared with a constant calibration reference voltage value which is (for example, only slightly) greater than the product of the maximum calibration current value and an electrical resistance of the sensor coil in order to determine whether or not a Wiegand voltage pulse was induced in the sensor coil during calibration. If the sensor coil voltage detected during the applying of the calibration current exceeds the calibration reference voltage value, it is assumed that a Wiegand voltage pulse was induced and consequently the direction of magnetization is set to the first magnetization direction value. To avoid an incorrect determination of the magnetization direction due to voltage fluctuations, it may also here be advantageous to specify a defined minimum exceeding time as the criterion for exceeding the value. To avoid so-called crippled pulses, the test current can, for example, be applied to the sensor coil after calibration even though the direction of magnetization is already known in order to completely magnetize the Wiegand wire.

The present invention also provides a Wiegand sensor arrangement.

The Wiegand sensor arrangement according to the present invention comprises a Wiegand wire and a sensor coil which radially surrounds the Wiegand wire. Such an arrangement of a Wiegand wire and a sensor coil is well known from the prior art and is also referred to as a Wiegand sensor.

According to the present invention, the Wiegand sensor arrangement comprises a magnetization direction determination unit which is electrically connected to the sensor coil and which is configured to carry out a method for determining a direction of magnetization of the Wiegand wire according to the present invention.

The magnetization direction determination unit is in particular configured to apply a test current that increases over time to the sensor coil and to detect a sensor coil voltage present at the sensor coil during this time. For this purpose, the magnetization direction determination unit typically comprises a controllable current source designed in any known manner, as well as a voltage measuring device designed in any known manner.

The magnetization direction determination unit is also configured, as already described above for the method according to the present invention, to determine a direction of magnetization of the Wiegand wire by comparing the sensor coil voltage detected during the applying of the test current with a reference voltage which increases simultaneously with the test current and which increases from a defined start reference voltage value to a defined end reference voltage value.

The magnetization direction determination unit can generally be implemented using any combination of hardware and/or software. The magnetization direction determination unit is, however, for example, implemented entirely in a single appropriately structured and programmed integrated circuit (IC), for example, in a so-called application-specific integrated circuit (ASIC).

The Wiegand sensor arrangement according to the present invention provides a simple and reliable determination of the direction of magnetization of the Wiegand wire via the magnetization direction determination unit which is configured to carry out a method according to the present invention.

In order to provide a reliable determination of the direction of magnetization of the Wiegand wire independently of the current temperature, an embodiment of the present invention provides that the Wiegand sensor arrangement according to the present invention has a temperature sensor, and that the magnetization direction determination unit comprises a temperature compensation module which is configured to define the start reference voltage value and/or the end reference voltage value on the basis of a temperature detected by the temperature sensor.

The temperature compensation module can, for example, comprise a reference value memory, which is also known as a look-up table, in which several temperature-specific start reference voltage values assigned to different temperatures and/or several temperature-specific end reference voltage values assigned to different temperatures are stored. This allows a simple temperature-dependent definition of the start reference voltage value and/or the end reference voltage value for which no particularly powerful computing unit is required.

The temperature compensation module may alternatively or additionally also comprise a calculation algorithm for a temperature-dependent calculation of the start reference voltage value and/or the end reference voltage value via a computing unit. This allows a temperature-dependent definition of the start reference voltage value and/or the end reference voltage value, for which no particularly large memory is required. It is in this case also conceivable, for example, that the calculation algorithm for calculating the start reference voltage value and/or the end reference voltage value uses one or more reference voltage values stored in the reference value memory.

In order to provide a particularly reliable determination of the direction of magnetization of the Wiegand wire, an embodiment of the Wiegand sensor arrangement according to the present invention can, for example, provide that the magnetization direction determination unit comprises a calibration module which is configured, as described above, to carry out a calibration before the applying of the test current. The calibration module is in particular configured to apply a calibration current, which can, for example, increase over time, to the sensor coil, wherein a maximum calibration current value corresponds to 1/N times a maximum test current value, to detect the sensor coil voltage during the applying of the calibration current, and to define the end reference voltage value as the sum of the start reference voltage value and N times a maximum sensor coil voltage value detected during the applying of the calibration current.

The calibration module can, for example, be configured to compare the sensor coil voltage detected during the applying of the calibration current with a constant calibration reference voltage value which is (for example, only slightly) greater than the product of the maximum calibration current value and an electrical resistance of the sensor coil, and, if the sensor coil voltage detected during the applying of the calibration current exceeds the calibration reference voltage value, to prevent the test current from being applied and to set the direction of magnetization to a first magnetization direction value.

Embodiments of the present invention are described below with reference to the enclosed drawings.

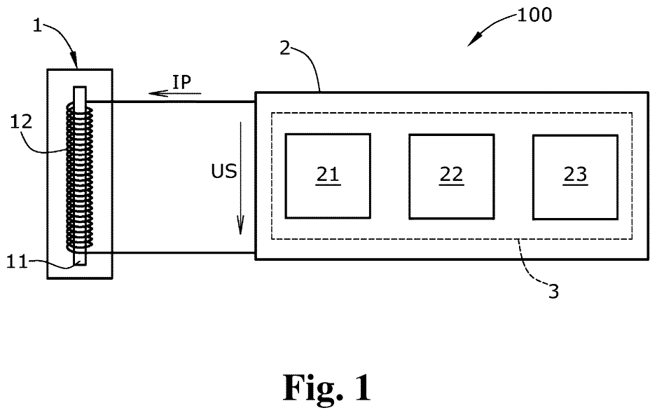

FIG. 1 shows a Wiegand sensor arrangement 100 with a Wiegand sensor 1. The Wiegand sensor 1 comprises a Wiegand wire 11 and a sensor coil 12 radially surrounding the Wiegand wire 11, and a circuit arrangement 2 which is electrically connected to the sensor coil 12. The circuit arrangement 2 comprises an application-specific integrated circuit (ASIC) 21, a microcontroller 22, and a memory 23, which together constitute a magnetization direction determination unit 3.

The ASIC 21 comprises a temperature sensor 211, a controlled current source circuit 212, a reference voltage generator circuit 213, and a comparator circuit 214. The microcontroller 22 comprises a software-implemented temperature compensation module 221, which is provided with a temperature T detected by the temperature sensor 211.

The temperature compensation module 221 is configured to define a current start reference voltage value URa and a current end reference voltage value URe based on the temperature T.

The temperature compensation module 221 comprises a reference value memory 2211 in which several temperature-specific start reference voltage values URa(T1)-URa(Tn) assigned to several different temperatures T1-Tn and several temperature-specific end reference voltage values URe(T1)-URe(Tn) assigned to several different temperatures T1-Tn are stored. The temperature compensation module 221 further comprises a calculation algorithm 2212 which is configured to calculate the current start reference voltage value URa and the current end reference voltage value URe based on the temperature T and the temperature-specific start reference voltage values URa(T1)-URa(Tn) and temperature-specific end reference voltage values URe(T1)-URe(Tn) stored in the reference value memory 2211.

It should be noted at this point that the temperature compensation module 221 can alternatively comprise only a reference value memory 2211 or only a calculation algorithm 2212. In the first case, the temperature compensation module 221 is configured to determine the present start reference voltage value URa and the present end reference voltage value URe by reading out the temperature-specific start reference voltage value URa(T) assigned to the temperature T and the temperature-specific end reference voltage value URe(T) assigned to the temperature T from the reference value memory 2211. In the second case, the calculation algorithm 2212 is configured to calculate the present start reference voltage value URa and the present end reference voltage value URe based only on the temperature T.

It should also be noted that the temperature compensation module 221 can also be configured to define only the present start reference voltage value URa or only the present end reference voltage value URe. The respective other reference voltage value URa, URe is in this case a constant.

The reference voltage generator circuit 213 is provided with the present start reference voltage value URa and the present end reference voltage value URe. The reference voltage generator circuit 213 is configured to generate a reference voltage UR that increases linearly with time t from the present start reference voltage value URa to the present end reference voltage value URe.

The controlled current source circuit 212 is configured to apply a test current Ip that increases linearly with time t to the sensor coil 12, wherein a maximum test current value Ip-max is specified via a maximum test current parameter PIp-max.

The comparator circuit 214 is provided with the sensor coil voltage US and the reference voltage UR. The comparator circuit 214 is configured to determine a magnetization direction value M, which indicates the magnetization direction of the Wiegand wire 11 by comparing the sensor coil voltage US with the reference voltage UR, and to write the magnetization direction value M into the memory 23. The comparator circuit 214 is in particular configured to write a first magnetization direction value M=1 into the memory 23 if the sensor coil voltage US exceeds the reference voltage UR for a defined minimum exceeding time, and to otherwise write a second magnetization direction value M=0 into the memory 23.

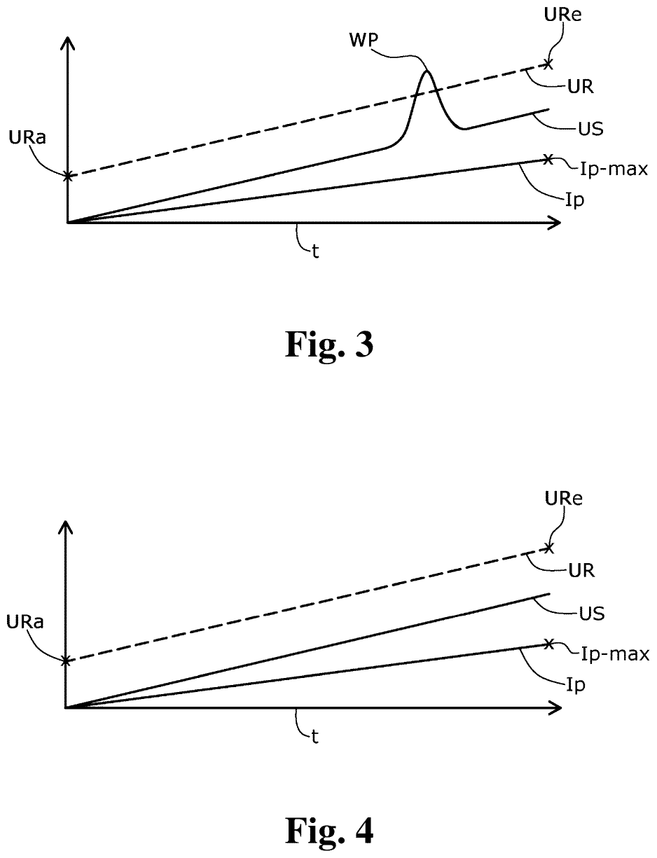

FIG. 3 shows, as an example, the temporal curves of the test current Ip, the sensor coil voltage US, and the reference voltage UR, for the case where a Wiegand voltage pulse WP is induced in the sensor coil 12. FIG. 4 shows the temporal curves of the test current Ip, the sensor coil voltage US, and the reference voltage UR from FIG. 3, but for the case where no Wiegand voltage pulse WP is induced in the sensor coil 12.

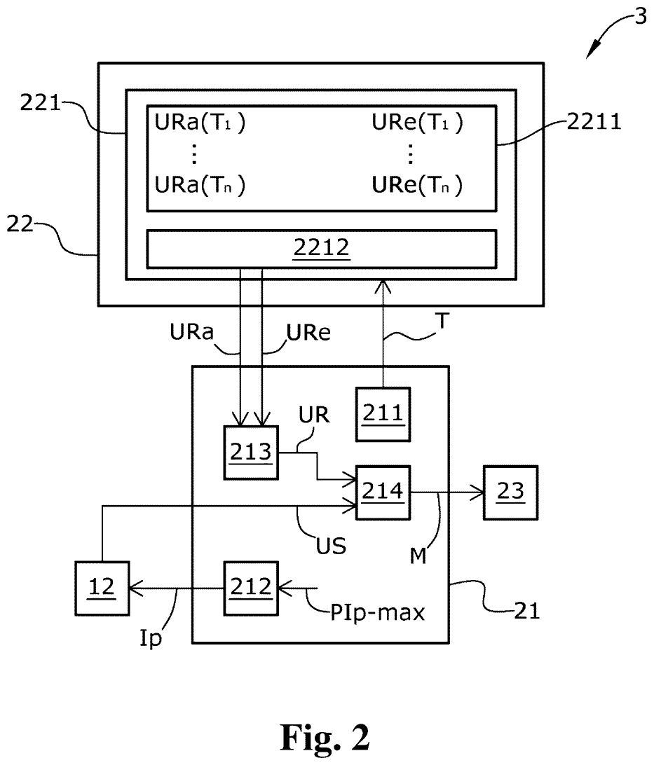

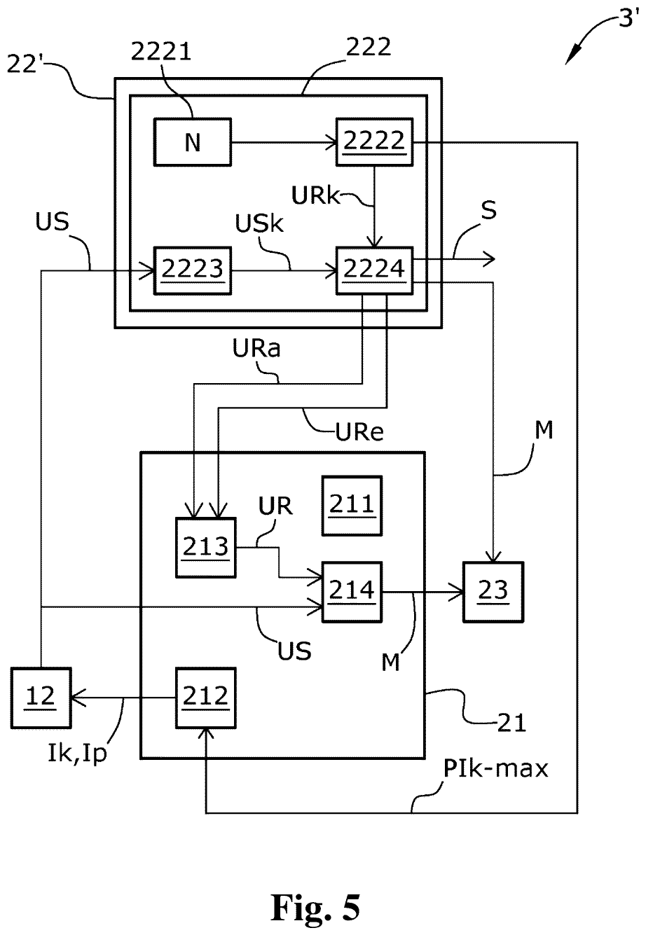

FIG. 5 shows an alternative magnetization direction determination unit 3′ according to the present invention, which is constituted by an alternatively configured microcontroller 22′ for the circuit arrangement 2 from FIG. 1. The microcontroller 22′ differs from the microcontroller 22 from FIG. 2 mainly in that the microcontroller 22′ has a calibration module 222 for defining the present start reference voltage value URa and the present end reference voltage value URe instead of the temperature compensation module 221.

The calibration module 222 comprises a calibration factor memory 2221 in which a calibration factor N is stored, a software-implemented calibration parameter determination module 2222, a software-implemented calibration sensor coil detection module 2223, and a software-implemented calibration evaluation module 2224.

The calibration parameter determination module 2222 is configured to determine, based on the calibration factor N, a maximum calibration current parameter PIk-max which corresponds to 1/N times the maximum test current parameter PIp-max. The calibration parameter determination module 2222 is further configured to determine a calibration reference voltage value URK which is (for example, only slightly) greater than the product of the maximum calibration current parameter PIk-max and an electrical resistance of the sensor coil 12. The calibration parameter determination module 2222 is configured to provide the maximum calibration current parameter PIk-max to the controlled current source circuit 212 so that the latter applies a calibration current Ik to the sensor coil 12 which increases linearly with time t up to a maximum calibration current value Ik-max specified by the maximum calibration current parameter PIk-max.

The calibration sensor coil detection module 2223 is configured to detect a calibration sensor coil voltage USk during the applying of the calibration current Ik.

The calibration evaluation module 2224 is configured to compare the calibration sensor coil voltage USk with the calibration reference voltage value URk. The calibration evaluation module 2224 is configured to, if the calibration sensor coil voltage USk does not exceed the calibration reference voltage value Urk, determine a maximum calibration sensor coil voltage value USk-max, to define the present start reference voltage value URa as the calibration reference voltage value URk, and to define the present end reference voltage value URe as the sum of the present start reference voltage value URa and N times the maximum calibration sensor coil voltage value USk-max. The calibration evaluation module 2224 is also configured to write the first magnetization direction value M=1 into the memory 23 if the calibration sensor coil voltage USk exceeds the calibration reference voltage value URk.

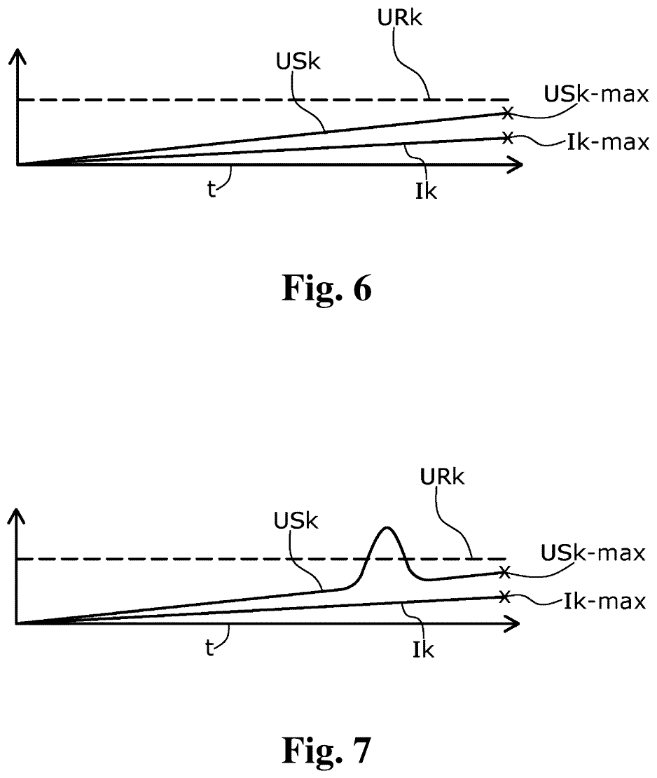

FIG. 6 shows, as an example, the temporal curves of the calibration current Ik and the calibration sensor coil voltage USk as well as the calibration reference voltage value URk for the case where no Wiegand voltage pulse WP is induced in the sensor coil 12. FIG. 7 shows the temporal curves of the calibration current Ik and the calibration sensor coil voltage USk as well as the calibration reference voltage value URk from FIG. 6, but for the case where a Wiegand voltage pulse WP is induced into the sensor coil 12.

The magnetization direction determination unit 3′is configured to, after the present start reference voltage value URa and the present end reference voltage value URe have been defined by the calibration module 222, generate the reference voltage UR via the reference voltage generator circuit 213 as described above, to apply the test current Ip to the sensor coil 12 via the controlled current source circuit 212, and to compare the sensor coil voltage US with the reference voltage UR during the applying of the test current Ip via the comparator circuit 214 in order to determine the magnetization direction value M.

The present invention is not limited to embodiments described herein; reference should be had to the appended claims.

### LIST OF REFERENCE CHARACTERS

100 Wiegand sensor arrangement
1 Wiegand sensor
11 Wiegand wire
12 Sensor coil
2 Circuit arrangement
21 Application-specific integrated circuit (ASIC)
211 Temperature sensor
212 Controlled current source circuit
213 Reference voltage generator circuit
214 Comparator circuit
22;22′ Microcontroller
221 Temperature compensation module
2211 Reference value memory
2212 Calculation algorithm
222 Calibration module
2221 Calibration factor memory
2222 Calibration parameter determination module
2223 Calibration sensor coil detection module
2224 Calibration evaluation module
23 Memory
3;3′ Magnetization direction determination unit
Ik Calibration current
Ik-max Maximum calibration current value
Ip Test current
Ip-max Maximum test current value
M Magnetization direction value
N Calibration factor
PIk-max Maximum calibration current parameter
PIp-max Maximum test current parameter
S Stop signal
t Time
T Detected temperature
T1-Tn Temperatures
UR Reference voltage
URa Start reference voltage value
URa(T1-Tn) Temperature-specific start reference voltage values
URe End reference voltage value
URe(T1-Tn) Temperature-specific end reference voltage values
URK Calibration reference voltage value
US Sensor coil voltage USk Calibration sensor coil voltage
USk-max Maximum calibration sensor coil voltage value
WP Wiegand voltage pulse

What is claimed is:

1-10. (canceled)

11. A method for determining a direction of magnetization of a Wiegand wire, the method comprising:
applying a test current which increases with time to a sensor coil which surrounds the Wiegand wire;
during the applying of the test current, detecting a sensor coil voltage which is present at the sensor coil; and
comparing the sensor coil voltage which is detected during the applying of the test current with a reference voltage which increases simultaneously with the test current so as to determine the direction of magnetization,
wherein,
the reference voltage increases from a start reference voltage value to an end reference voltage value.

12. The method as recited in claim 11, further comprising:
detecting a temperature,
wherein,
at least one of the start reference voltage value and the end reference voltage value is defined based on the temperature detected.

13. The method as recited in claim 11, further comprising:
applying a calibration current to the sensor coil prior to applying the test current, wherein a maximum calibration current value corresponds to 1/N times a maximum test current value; and
detecting a calibration sensor coil voltage which is present at the sensor coil during the applying of the calibration current,
wherein,
the end reference voltage value is defined as a sum of the start reference voltage value and N times a maximum calibration sensor coil voltage value which is detected during the applying of the calibration current.

14. The method as recited in claim 13, further comprising:
comparing the calibration sensor coil voltage with a calibration reference voltage value which is greater than a product of the maximum calibration current value and an electrical resistance of the sensor coil, and
if the calibration sensor coil voltage exceeds the calibration reference voltage value, setting the direction of magnetization to a first direction of magnetization value.

15. A Wiegand sensor arrangement comprising:
a Wiegand wire;
a sensor coil which surrounds the Wiegand wire; and
a magnetization direction determination unit which is configured:
to apply a test current which increases with time to the sensor coil,
to detect a sensor coil voltage which is present at the sensor coil during the applying of the test current, and
to determine a direction of magnetization of the Wiegand wire by comparing the sensor coil voltage which is detected during the applying of the test current with a reference voltage which increases simultaneously with the test current,
wherein,
the reference voltage increases from a start reference voltage value to an end reference voltage value.

16. The Wiegand sensor arrangement as recited in claim 15, further comprising:
a temperature sensor which is configured to detect a temperature,
wherein,
the magnetization direction determination unit comprises a temperature compensation module which is configured to define at least one of the start reference voltage value and the end reference voltage value on the basis of the temperature detected by the temperature sensor.

17. The Wiegand sensor arrangement as recited in claim 16, wherein the temperature compensation module comprises a reference value memory in which at least one of a plurality of temperature-specific start reference voltage values which are assigned to different temperatures and a plurality of temperature-specific end reference voltage values which are assigned to different temperatures are stored.

18. The Wiegand sensor arrangement as recited in claim 16, wherein the temperature compensation module comprises a calculation algorithm for calculating at least one of the start reference voltage value and the end reference voltage value as a function of the temperature.

19. The Wiegand sensor arrangement as recited in claim 15, wherein the magnetization direction determination unit comprises a calibration module which is configured:
to apply a calibration current to the sensor coil before the applying of the test current, wherein a maximum calibration current value corresponds to 1/N times a maximum test current value,
to detect a calibration sensor coil voltage which is present at the sensor coil during the applying of the calibration current, and
to define the end reference voltage value as a sum of the start reference voltage value and N times a maximum calibration sensor coil voltage value which is detected during the applying of the calibration current.

20. The Wiegand sensor arrangement as recited in claim 19, wherein the calibration module is further configured:
to compare the calibration sensor coil voltage with a calibration reference voltage value which is greater than a product of the maximum calibration current value and an electrical resistance of the sensor coil, and
to set the direction of magnetization to a first direction of magnetization value if the calibration sensor coil voltage exceeds the calibration reference voltage value.
